(19) United States
(12) Patent Application Publication
(10) Pub. No.: US 2019/0230788 A1
(43) Pub. Date: Jul. 25, 2019

(54) SUBSTRATE WITH STRESS RELIEVING FEATURES

(71) Applicant: Intel Corporation, Santa Clara, CA (US)

(72) Inventor: Mao Guo, Shanghai (CN)

(21) Appl. No.: 16/336,599

(22) PCT Filed: Sep. 30, 2016
(86) PCT No.: PCT/CN2016/101168

§ 371 Date: Mar. 26, 2019

(51) Int. Cl. H05K 1/02

(52) U.S. Cl. CPC H05K 1/0271; H05K 1/0284; H05K 2203/1316; H05K 2201/09063; H05K 2201/10734; H05K 2201/0187

(57) ABSTRACT

Various examples disclosed relate to a substrate for a semiconductor. The substrate includes a first conducting layer, having a first surface and an opposite second surface. The substrate further includes a second conducting layer extending in a direction substantially parallel to the first conducting layer. The second conducting layer includes a third surface and an opposite fourth surface. A first dielectric layer is disposed between the second surface of the first conducting layer and the third surface of the second conducting layer. The first dielectric layer includes a first dielectric material and a fiber. Slots extends between the first conducting layer and the second conducting layer. Each of the slots is defined by an internal surface of the first conducting layer, the second conducting layer, and the first dielectric layer.

### BACKGROUND

Semiconductor devices including ball grid array(BGA) and chip scale package(CSP) are the package types widely used in industry now due to its relatively small form factor and good electrical performance. Different parts of these devices have different coefficient of expansion (CTE) which may result in different warpage performance during temperature change at surface mount process or operation. This may decrease performance of the device.

### BRIEF DESCRIPTION OF THE FIGURES

In the drawings, which are not necessarily drawn to scale, like numerals describe substantially similar components throughout the several views. The drawings illustrate generally, by way of example, but not by way of limitation, various embodiments discussed in the present document.

FIG. 1 is a side cutaway view of an example semiconductor device.

FIG. 2 is a schematic sectional view a substrate of the semiconductor device.

FIG. 3 is a top schematic view showing a first layer of the substrate.

FIG. 4 is a schematic side view showing the substrate assembled as a 4-layer substrate.

FIG. 5 is a schematic side view of a semiconducting device 10 with an 8-die package formed on the substrate.

FIG. 6 is a flow chart showing a method of forming the substrate.

FIG. 7 is block diagram of an electronic system, according to an embodiment.

### DETAILED DESCRIPTION OF THE INVENTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation.

In the methods described herein, the acts may be carried out in any order without departing from the principles of the invention, except when a temporal or operational sequence is explicitly recited. Furthermore, specified acts may be carried out concurrently unless explicit language recites that they be carried out separately. For example, a claimed act of doing X and a claimed act of doing Y may be conducted simultaneously within a single operation, and the resulting process will fall within the literal scope of the claimed process.

The term “about” as used herein may allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

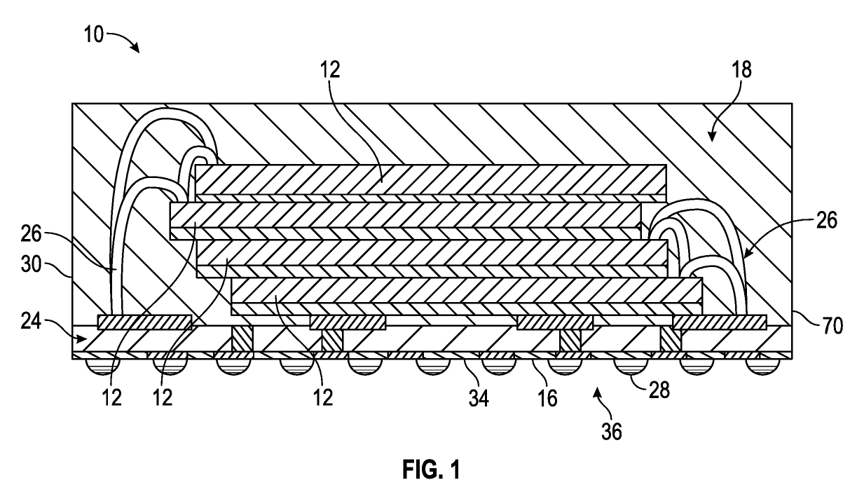

FIG. 1 is a side cutaway view of an example of semiconductor device 10 in accordance with one or more aspects described herein. Semiconductor device 10 of FIG. 1 may include electrical components such as silicon dies 12 that may include one or more active and/or passive components, such as electrical and/or optical components. For example, silicon dies 12 may include components such as one or more resistor transistors, capacitors, diodes, and/or memory cells, with one or more conducting lines interconnecting the same.

Semiconductor device 10 of FIG. 1 may be considered a ball grid array package, Silicon die 12 may be at least partially surrounded in one or more lateral directions by extension layer 18. Extension layer 18 may be made of a plastic material, mold compound, or other non-conducting material, and may be directly adjacent to and/or in contact with one or more lateral sides of silicon dies 12. Extension layer 18 may artificially extend the surface area of silicon die 12, and may be made of a material different than the material of silicon die 12. In doing so, extension layer 18 may extend the area of lower surface 16 of silicon die 12 by an area that may be flush (at the same level) and/or continuous with lower surface 16 of silicon die 12. However, the lower surface of extension layer 18 may be at a slightly different level than lower surface 16 of silicon die 12, if desired.

A ball grid array (BGA) of solder balls 28 is disposed on the underside of substrate 24. The BGA may, in turn, be electrically coupled to (e.g., soldered to) a circuit board such as a PCB board. Thus, the example semiconductor devices described herein may be placed on a circuit board as part of a larger circuit and/or device.

Substrate 24 may be made of, or otherwise include, a printed circuit board (PCB), and may be formed as a dielectric substrate on and/or in which electrically conducting layers may be formed to provide the above-mentioned interconnects 34. For example, substrate 24 may be formed of a network of the conducting layers. To provide a potentially more reliable device, the material(s) of substrate 24 may be selected to have a coefficient of thermal expansion (CTE) close to that of the PCB onto which ball grid array 36 is to be soldered. In doing so, this may reduce the possibility of substrate 24 and the PCB board external to the semiconductor device pulling away from each other and potentially causing circuit disconnections or short-circuiting due to environmental temperature variations. Wires 26 connect substrate 24 to silicon dies 12. Wires 26 can be formed from many different materials including gold.

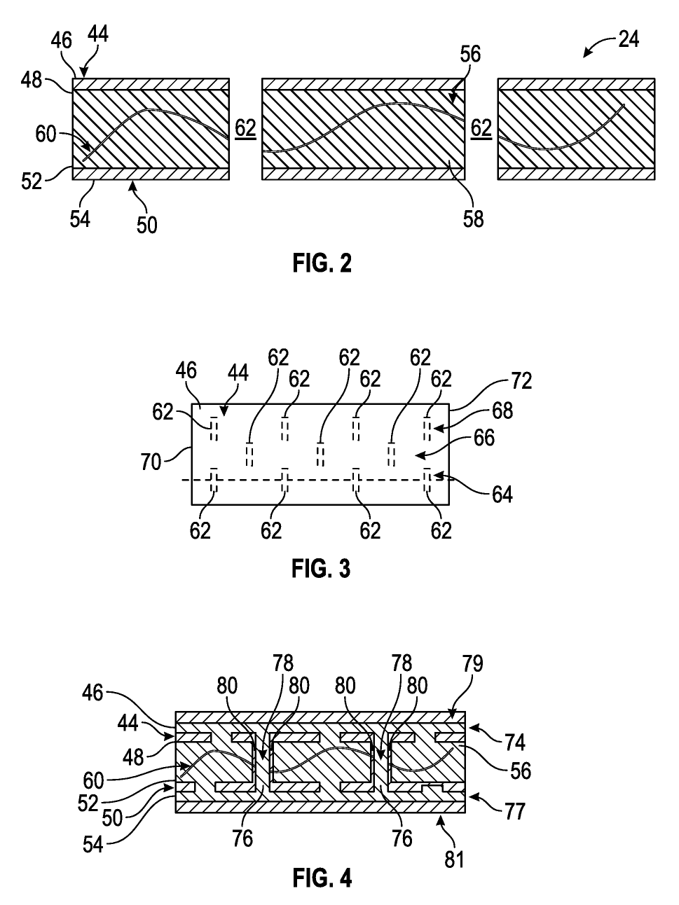

FIG. 2 is a schematic sectional view of substrate 24. Substrate 24 includes first conducting layer 44, which includes first surface 46 and opposite second surface 48. Substrate 24 further includes second conducting layer 50. Second conducting layer extends in a direction substantially parallel to the first conducting layer and has a generally equal length and width as first conducting layer 44. Second conducting layer 50 includes third surface 52 and opposite fourth surface 54. First conducting layer 44, is formed from a conducting material such as copper. Second conducting layer 50 is also formed from a conducting layer such as copper.

First dielectric layer 56 is disposed between second surface 48 of first conducting layer 44 and third surface 52 of second conducting layer 50. First dielectric layer 56 is formed of first dielectric material 58, which is interspersed with fiber 60. First dielectric material 58 may be selected from the group including, a polyimide, a bismaleimide-triazine (BT) resin, an epoxy resin, a polyurethane, a benzocyclobutene (BCB), a high-density polyethylene (HDPE), or combinations thereof. Fiber 60 may help to reinforce first dielectric layer 56, which may increase the strength or stiffness of substrate 24. A suitable material to form fiber 60 from is glass fiber although other fibers may be used. In some examples first dielectric material 58 is about 80% (w/w) to about 98% (w/w) of the dielectric layer and fiber 60 is about 2% (w/w) to about 20% (w/w) of first dielectric layer 56.

A plurality of slots 62 extend between first conducting layer 44 and second conducting layer 50. Each of the plurality of the slots 62 is defined by internal surface of first conducting layer 44, second conducting layer 50, and first dielectric layer 56. Slots 62 may have many different profiles. For example, at least one of slots 62 may have a square profile, a rectangular profile, a generally elliptical profile, a generally elongated race-track profile, or any polygonal profile. In some examples at least one of slots 62 may have the same profile as another slot 62. In other examples each slot 62 may have a different profile or the same profile.

Slots 62 may be arranged into rows on substrate 24 extending from first end 70 of substrate 24 to second end 72 of substrate 24. FIG. 3 is a top schematic view showing first conducting layer 44 of substrate 24. As shown, slots 62 are arranged in first row 64, second row 66, and third row 68. Each of slots 62 has a generally elongated racetrack profile. As shown in FIG. 3, each of slots 62 of first row 64, second row 66, and third row 68 are staggered with respect to each other. In other examples each of slots 62 of first row 64, second row 66, and third row 68 are directly aligned with respect to each other.

FIG. 4 is a schematic side view showing an example of substrate 24 assembled as a 4-layer substrate. In addition to those components discussed in FIGS. 1-3, FIG. 4 shows additional layers of substrate 24. Specifically, FIG. 4 shows second dielectric layer 74, which is disposed on first surface 46 of first conducting layer 44. Third dielectric layer 77 is disposed on fourth surface 54 of second conducting layer 50. Second dielectric layer 74 and third dielectric layer 77 are formed from second dielectric material 76. In some examples second dielectric material 76 is the same material as first dielectric material 58. Both second dielectric layer 74 and third dielectric layer 77 are free of fiber 60. FIG. 4 further shows third conducting layer 77, which is disposed on second dielectric layer 74. FIG. 4 also shows third conducting layer 79, which is disposed on third conducting layer 79. Similarly to first conducting layer 44 and second conducting layer 50, third conducting layer 79 and fourth conducting layer 81 are formed from a conducting material. One such material is copper. The copper may be in the form of a copper foil or a more robust copper sheet. Typically, first conducting layer 44 and second conducting layer 50 are formed from a copper sheet, whereas third conducting layer 79 and third conducting layer 79 are formed from a copper foil. In some examples, the coper sheet or foil may be formed as a copper trace.

Each of first conducting layer 44, second conducting layer 50, third conducting layer 79, and fourth conducting layer 81 may serve different functions in substrate 24. For example in a four-layer substrate, first conducting layer 44 may be adapted to be a power layer and second conducting layer 50 may be adapted to be a ground layer. Additionally, third conducting layer 79 and fourth conducting layer 81 may be adapted to be a signal layer that is connected to an electrical component such as a silicon die. In other examples the function of each layer may vary. Additionally, in other examples of substrate 24 such as a 6-layer substrate or 8-layer substrate the function of each layer may vary.

As shown in FIG. 4 slots 62 are filled to form pedestals 78. As described herein pedestals 78 can be filled with a dielectric material or air, or any material that is more flexible than that of first dielectric layer 56. In order to maintain an electrical connection between each conducting layer, strips 80, which are also formed from a conducting material, are disposed between pedestal 78 and first dielectric layer 56 to connect first conducting layer 44 and second conducting layer 50.

Pedestals 78 are formed from second dielectric material 76 and have a profile that is commensurate with slot 62. Because pedestals 78 are formed from the second dielectric material 76, pedestals 78 share the same dielectric material as third conducting layer 79 and fourth conducting layer 81. A difference between pedestals 78 and surrounding first dielectric layer 56 is that pedestals 78 are free of fiber 60. Thus, the first dielectric layer 56 is a non-homogenous layer in that it contains areas including fiber 60 as well as areas defined by pedestal 78 that do not include fiber 60. While both regions will have similar or equivalent electrical and thermal properties they differ in their flexibility. Specifically, due to fibers 60 first dielectric layer 56 is stiffer than pedestals 78. Thus pedestals 78 are more flexible than first dielectric layer 56.

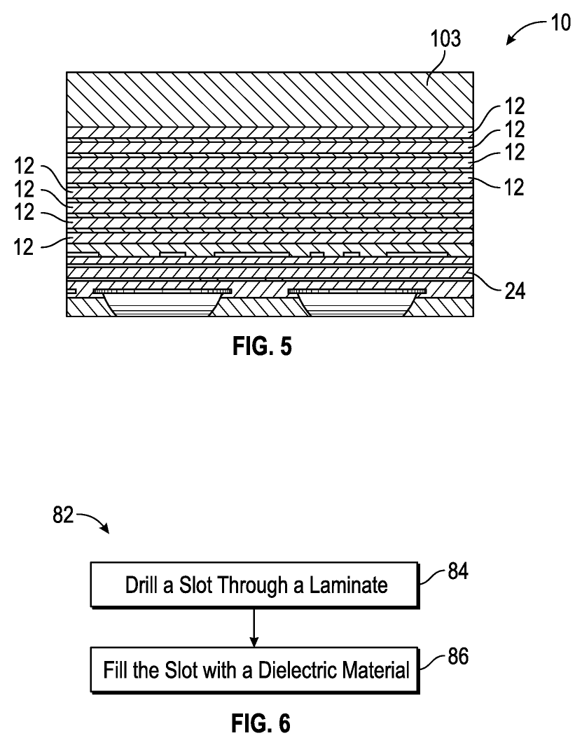

Because pedestals 78 are more flexible than first dielectric layer 56 the overall warpage of substrate 24, and semiconductor device 10 as a whole, may be reduced. Warpage of semiconductor device 10 typically occurs at both room temperature at a reflow temperature. In order to attempt to accommodate warpage some semiconducting devices are designed to increase the clearance between underfill layer 103 and extension layer 18 and silicon die 12. This technique however become less effective if multiple silicon die 12, or other electrical components are stacked up on each other. This is because the size of semiconducting device 10 must become larger in order to not only surround the additional dies 12 but to still provide adequate clearance to accommodate any warpage of substrate 24. An example, of semiconducting device 10 with an 8-die package formed on substrate 24 is shown in FIG. 5.

An advantage to forming slots 62 or pedestals 78, however, is that warpage of substrate 24 is reduced because pedestals 78 are able to absorb stresses imparted to substrate by heat and prevent or reduce warpage compared to a substrate without pedestals 78 or slots 62. Because warpage is prevented or reduced there is less of a need to increase clearance between underfill layer 103 and extension layer 18 and silicon die 12. This results in less empty space in semiconducting device 10 as well as an overall smaller profile semiconductor device 10.

Substrate 24 may be formed in many different ways as an example, method 82 drilling step 86 and filling step 84. FIG. 6 is a flow chart showing method 82. Drilling step 86 includes drilling a slot through a laminate. Drilling may be accomplished through laser or mechanical drilling. The laminate includes first conducting layer 44. First conducting layer includes first surface 46 and opposite second surface 48. The laminate further includes second conducting layer 50, which extends in a direction substantially parallel to the first conducting layer 44. Once slot 62 is drilled, it is filled with second dielectric material 76 in filling step 84.

Filling step 84 includes laminating third conducting layer 79 to first conducting layer. Third conducting layer 79 includes a prepreg layer that is a dielectric resin.

During lamination the dielectric resin contacts first conducting layer 44. Further during lamination at least a portion of the of the dielectric resin fills slot 62 as third conducting layer 79 is laminated to first conducting layer 44. After lamination, at least a portion of the dielectric resin becomes pedestal 78. Simultaneously during filling step 84 fourth conducting layer 81 is laminated to second conducting layer 50. Fourth conducting layer 81 includes a prepreg layer that is a dielectric resin. During lamination the dielectric resin contacts second conducting layer 50. Further during lamination at least a portion of the of the dielectric resin fills slot 62 as fourth conducting layer 81 is laminated to second conducting layer 50. After lamination at least a portion of the dielectric resin becomes pedestal 78. In other examples lamination of third conducting layer 79 and fourth conducting layer 81 may occur at different times. Method 82 may further include plating slot 62 with a layer of conducting material, such as copper, that connects first conducing layer 44 to the second conducting layer 50. Plating may be accomplished through electrochemical deposition techniques.

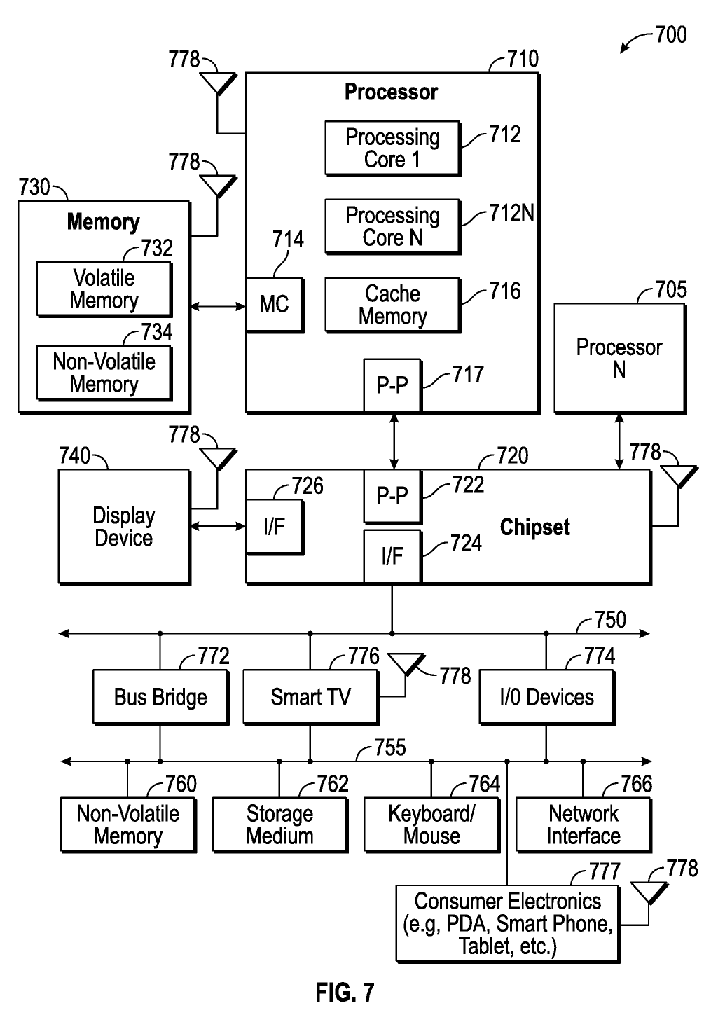

FIG. 7 illustrates a system level diagram, according to an embodiment of the invention. For instance, FIG. 7 depicts an example of an electronic device (e.g., system) including substrate 24. FIG. 7 is included to show an example of a higher level device application for the present invention. In an embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In an embodiment, processor 710 has one or more processing cores 712 and 712N, where 712N represents the Nth processor core inside processor 710 where N is a positive integer. In an embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In an embodiment, the wireless antenna interface 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In an embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the invention, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices 772, 776, 774, 760, 762, 764, 766, 777, etc. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a plasma display, cathode ray tube (CRT) display, or any other form of visual display device. In some embodiments of the invention, processor 710 and chipset 720 are merged into a single SOC. In addition, chipset 720 connects to one or more buses 750 and 755 that interconnect various elements 774, 760, 762, 764, and 766. Buses 750 and 755 may be interconnected together via a bus bridge 772. In an embodiment, chipset 720 couples with a non-volatile memory 760, a mass storage device(s) 762, a keyboard/mouse 764, and a network interface 766 via interface 724 and/or 704, smart TV 776, consumer electronics 777, etc.

In an embodiment, mass storage device 762 includes, but is not limited to, a solid state drive, a hard disk drive, a universal serial bus flash memory drive, or any other form of computer data storage medium. In an embodiment, network interface 766 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In an embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) may be incorporated into processor core 712.

Various embodiments of the present invention may have certain advantages, some of which are unexpected. For example the varying thickness of elastomer layer 18 concentrates the strain caused by stresses imparted to system 10 in stretchable areas that were designed for it, while reducing strain in areas that are not desired to stretch. In contrast systems with a substantially uniform thickness across an elastomer layer or other encapsulating layer do not concentrate strain in different areas. As a result areas that were not designed to stretch may stretch and be damaged. Therefore the mechanical reliability and durability of systems having a varying thickness of elastomer layer 18 are greatly improved by comparison. Specifically, varying the thickness across elastomer layer 18 systems show increased durability in cyclical stretching tests and in single stretching strength tests. For example, various embodiments of system ten may show an increase in durability of approximately 3 to 10 times that of a system that does not have a varying thickness.

### Additional Embodiments

The following exemplary embodiments are provided, the numbering of which is not to be construed as designating levels of importance:

Embodiment 1 provides a substrate for a semiconductor comprising:

a first conducting layer: comprising

a first surface; and

an opposite second surface;

a second conducting layer extending in a direction substantially parallel to the first conducting layer, comprising:

a third surface; and

an opposite fourth surface;

a first dielectric layer disposed between the second surface of the first conducting layer and the third surface of the second conducting layer comprising:

a first dielectric material; and

a plurality of slots extending between the first conducting layer and the second conducting layer, wherein each of the slots is defined by an internal surface of the first dielectric layer and at least one of the first conducting layer and the second conducting layer, and the first dielectric layer.

Embodiment 2 provides the substrate of Embodiment 1, wherein the first conducting layer is formed from copper.

Embodiment 3 provides the substrate of any one of Embodiments 1-2, wherein the second conducting layer is formed from copper.

Embodiment 4 provides the substrate of any one of Embodiments 1-3, wherein the first dielectric material is selected from the group consisting of, a polyimide, a bismaleimide-triazine (BT) resin, an epoxy resin, a polyurethane, a benzocyclobutene (BCB), a high-density polyethylene (HDPE), or combinations thereof.

Embodiment 5 provides the substrate of any one of Embodiments 1-4, wherein each of the slots is defined by an internal surface of the first dielectric layer, the first conducting layer, and the second conducting layer.

Embodiment 6 provides the substrate of any one of Embodiments 1-5, wherein the first dielectric material is about 80% (w/w) to about 98% (w/w) of the first dielectric layer.

Embodiment 7 provides the substrate of any one of Embodiments 1-6, wherein the fiber is about 2% (w/w) to about 20% (w/w) of the first dielectric layer.

Embodiment 8 provides the substrate of any one of Embodiments 1-7, wherein at least one of the slots has a circular profile.

Embodiment 9 provides the substrate of any one of Embodiments 1-8, wherein at least one of the slots has a square profile.

Embodiment 10 provides the substrate of any one of Embodiments 1-9, wherein at least one of the slots has a rectangular profile.

Embodiment 11 provides the substrate of any one of Embodiments 1-10, wherein at least one of the slots has a generally elliptical profile.

Embodiment 12 provides the substrate of any one of Embodiments 1-11, wherein at least one of the slots has a generally elongated race-track profile.

Embodiment 13 provides the substrate of any one of Embodiments 1-12, wherein at least one of the slots has a polygonal profile.

Embodiment 14 provides the substrate of any one of Embodiments 1-13, wherein a profile of at least one of the slots is the same as a profile of at least one of another of the slots.

Embodiment 15 provides the substrate of any one of Embodiments 1-14 wherein a set of the slots are arranged in a first row of slots extending from a first end of the substrate to a second end of the substrate.

Embodiment 16 provides the substrate of any one of Embodiments 1-15, wherein a second set of the slots are arranged in a second row of slots extending from the first end of the substrate to the second end of the substrate.

Embodiment 17 provides the substrate of any one of Embodiments 1-16, wherein each of the slots of the first row are directly aligned with a corresponding slot of the second row.

Embodiment 18 provides the substrate of any one of Embodiments 1-17, wherein each of the slots of the first row and each of the slots of the second row are staggered with respect to each other.

Embodiment 19 provides the substrate of any one of Embodiments 1-18, wherein each of the slots is filled with a second dielectric material that is free of the fiber.

Embodiment 20 provides the substrate of any one of Embodiments 1-19, wherein the second dielectric material disposed in the slot is the same material of the first dielectric material.

Embodiment 21 provides the substrate of any one of Embodiments 1-20, and further comprising:

a strip formed from a conducting material extending from the first conducting layer to the second conducting layer through the slot and around the second dielectric material filling the slot.

Embodiment 22 provides the substrate of any one of Embodiments 1-21, and further comprising:

a second dielectric layer disposed on the first surface of the first conducting layer.

Embodiment 23 provides the substrate of any one of Embodiments 1-22, and further comprising:

a third dielectric layer disposed on the fourth surface of the second conducting layer.

Embodiment 24 provides the substrate of any one of Embodiments 1-23, wherein the second dielectric layer and the third dielectric layer comprise the same dielectric material as the second dielectric material.

Embodiment 25 provides the substrate of any one of Embodiments 1-24, wherein the second dielectric layer and the third dielectric layer are free of the fiber.

Embodiment 26 provides the substrate of any one of Embodiments 1-25, wherein the dielectric material located in each of the slots comprises the same dielectric material as the second dielectric layer and the third dielectric layer.

Embodiment 27 provides the substrate of any one of Embodiments 1-26, and further comprising:

a third conducting layer disposed on the second dielectric layer.

Embodiment 28 provides the substrate of any one of Embodiments 1-27, and further comprising:

a fourth conducting layer disposed on the third conducting layer.

Embodiment 29 provides the substrate of any one of Embodiments 1-28, wherein at least one of the first conducting layer, second conducting layer, third conducting layer, and the fourth conducting layer is a copper foil.

Embodiment 30 provides the substrate of any one of Embodiments 1-29, wherein at least one of the first conducting layer, the second conducting layer, the third conducting layer, and the fourth conducting layer is a copper trace.

Embodiment 31 provides the substrate of any one of Embodiments 1-30, wherein the third conducting layer is formed from copper.

Embodiment 32 provides the substrate of any one of Embodiments 1-31, wherein the fourth conducting layer is formed from copper.

Embodiment 33 provides the substrate of any one of Embodiments 1-32, wherein the first conducting layer is adapted to be a power layer.

Embodiment 34 provides the substrate of any one of Embodiments 1-33, wherein the second conducting layer is adapted to be a ground layer.

Embodiment 35 provides the substrate of any one of Embodiments 1-34, wherein the first conducting layer is adapted to be a signal layer.

Embodiment 36 provides the substrate of any one of Embodiments 1-35, wherein the second conducting layer is adapted to be a signal layer.

Embodiment 37 provides a semiconducting device comprising:

a substrate comprising:
a first conducting layer: comprising

a first surface; and

an opposite second surface;

a second conducting layer extending in a direction substantially parallel to the first conducting layer, comprising:

a third surface; and

an opposite fourth surface;

a first dielectric layer disposed between the second surface of the first conducting layer and the third surface of the second conducting layer, comprising:

a first dielectric material; and

reinforcing fibers; and

a plurality of pedestals extending through the first conducting layer, the first dielectric layer and the second conducting layer, wherein the pedestals are each formed from a second dielectric material;
an electrical component connected to the substrate; and
a mold encasing the substrate and the electrical component.

Embodiment 38 provides the semiconducting device of Embodiment 37, wherein each of the pedestals is free of the fiber.

Embodiment 39 provides the semiconducting device of any one of Embodiments 37-38, wherein the first conducting layer is formed from copper.

Embodiment 40 provides the semiconducting device of any one of Embodiments 37-39, wherein the second conducting layer is formed from copper.

Embodiment 41 provides the semiconducting device of any one of Embodiments 37-40, wherein the first dielectric material is selected from the group consisting of, a polyimide, a bismaleimide-triazine (BT) resin, an epoxy resin, a polyurethane, a benzocyclobutene (BCB), a high-density polyethylene (HDPE), or combinations thereof.

Embodiment 42 provides the semiconducting device of any one of Embodiments 37-41, wherein the fiber is a glass fiber.

Embodiment 43 provides the semiconducting device of any one of Embodiments 37-42, wherein at least one of the pedestals has a circular profile.

Embodiment 44 provides the semiconducting device of any one of Embodiments 37-43, wherein at least one of the pedestals has a square profile.

Embodiment 45 provides the semiconducting device of any one of Embodiments 37-44, wherein at least one of the pedestals has a rectangular profile.

Embodiment 46 provides the semiconducting device of any one of Embodiments 37-45, wherein at least one of the pedestals has a generally elliptical profile.

Embodiment 47 provides the semiconducting device of any one of Embodiments 37-46, wherein at least one of the pedestals has a generally elongated race-track profile.

Embodiment 48 provides the semiconducting device of any one of Embodiments 37-47, wherein at least one of the pedestals has a polygonal profile.

Embodiment 49 provides the semiconducting device of any one of Embodiments 37-48, wherein a profile of at least one of the pedestals is the same as a profile of at least one of another of the pedestals.

Embodiment 50 provides the semiconducting device of any one of Embodiments 37-49, wherein a set of the pedestals are arranged in a first row of pedestals extending from a first end of the substrate to a second end of the substrate.

Embodiment 51 provides the semiconducting device of any one of Embodiments 37-50, wherein a second set of the pedestals are arranged in a second row of pedestals extending from the first end of the substrate to the second end of the substrate.

Embodiment 52 provides the semiconducting device of any one of

Embodiments 37-51, wherein each of the pedestals of the first row are directly aligned with a corresponding pedestal of the second row.

Embodiment 53 provides the semiconducting device of any one of Embodiments 37-52, wherein each of the pedestals of the first row and each of the pedestals of the second row are staggered with respect to each other.

Embodiment 54 provides the semiconducting device of any one of Embodiments 37-53, wherein the dielectric material forming each of the pedestals is the same dielectric material of the dielectric layer.

Embodiment 55 provides the semiconducting device of any one of Embodiments 37-54, and further comprising:

a plurality of strips formed from a conducting material, wherein each of the strips is disposed between at least one of pedestals and the first dielectric layer.

Embodiment 56 provides the semiconducting device of any one of Embodiments 37-55, and further comprising:

a second dielectric layer disposed on the first surface of the first conducting layer.

Embodiment 57 provides the semiconducting device of any one of Embodiments 37-56, and further comprising:

a third dielectric layer disposed on the fourth surface of the second conducting layer.

Embodiment 58 provides the semiconducting device of any one of Embodiments 37-57, wherein the second dielectric layer and the third dielectric layer comprise the same dielectric material.

Embodiment 59 provides the semiconducting device of any one of Embodiments 37-58, wherein the second dielectric layer and the third dielectric layer are free of the fiber.

Embodiment 60 provides the semiconducting device of any one of Embodiments 37-59, wherein the second dielectric material forming the pedestals comprises the same dielectric material as the second dielectric layer and the third dielectric layer.

Embodiment 61 provides the semiconducting device of any one of Embodiments 37-60, and further comprising:

a third conducting layer disposed on the second dielectric layer.

Embodiment 62 provides the semiconducting device of any one of Embodiments 37-61, and further comprising:

a fourth conducting layer disposed on the third conducting layer.

Embodiment 63 provides the semiconducting device of any one of Embodiments 37-62, wherein at least one of the first conducting layer, second conducting layer, third conducting layer, and fourth conducting layer is a copper foil.

Embodiment 64 provides the semiconducting device of any one of Embodiments 37-63, wherein at least one of the first conducting layer, second conducting layer, third conducting layer, and fourth conducting layer is a copper trace.

Embodiment 65 the semiconducting device of any one of Embodiments 37-64, wherein the third conducting layer is formed from copper.

Embodiment 66 provides the semiconducting device of any one of Embodiments 37-65, wherein the fourth conducting layer is formed from copper.

Embodiment 67 provides the semiconducting device of any one of Embodiments 37-66, wherein the first conducting layer is adapted to be a power layer.

Embodiment 68 provides the semiconducting device of any one of Embodiments 37-67, wherein the second conducting layer is adapted to be a ground layer.

Embodiment 69 provides the semiconducting device of any one of Embodiments 37-68, wherein the first conducting layer is adapted to be a signal layer.

Embodiment 70 provides the semiconducting device of any one of Embodiments 37-69, wherein the second conducting layer is adapted to be a signal layer.

Embodiment 71 provides the semiconducting device of any one of Embodiments 37-70, wherein the electrical component is connected to the fourth conducting layer.

Embodiment 72 provides the semiconducting device of any one of Embodiments 37-71, and further comprising:

a wire connected to the fourth conducting layer and the electrical component.

Embodiment 73 provides the semiconducting device of any one of Embodiments 37-72, wherein the electrical component is a silicon die.

Embodiment 74 provides the semiconducting device of any one of Embodiments 37-73, wherein the pedestals are more flexible than the first dielectric layer.

Embodiment 75 provides the semiconducting device of any one of Embodiments 37-74, the substrate is undergoes less warpage in response to being exposed to a temperature at or above room temperate as compared to a substrate that does not include at least one of the pedestals.

Embodiment 76 provides a method of forming a substrate comprising:

drilling a slot through a laminate, wherein the laminate comprises:

a first conducting layer comprising:
a first surface; and
an opposite second surface;

a second conducting layer extending in a direction substantially parallel to the first conducting layer, comprising:
a third surface; and
an opposite fourth surface; and

a first dielectric layer disposed between the second surface of the first conducting layer and the third surface of the second conducting layer comprising:
a first dielectric material; and
reinforcing fibers; and
   filling the slot with a second dielectric material.

Embodiment 77 provides the method of Embodiment 76, and further comprising laminating a third conducting layer to the first conducting layer.

Embodiment 78 provides the method of any one of Embodiments 76-77, wherein a dielectric resin is disposed on the third conducting layer.

Embodiment 79 provides the method of any one of Embodiments 76-78, wherein the dielectric resin contacts the first conducting layer.

Embodiment 80 provides the method of any one of Embodiments 76-79, wherein at least a portion of the of the dielectric resin fills the slot as the third conducting layer is laminated to the first conducting layer.

Embodiment 81 provides the method of any one of Embodiments 76-80, and further comprising laminating a fourth conducting layer to the second conducting layer.

Embodiment 82 provides the method of any one of Embodiments 76-81, wherein a dielectric resin is disposed on the fourth conducting layer.

Embodiment 83 provides the method of any one of Embodiments 76-82, wherein the dielectric resin contacts the second conducting layer.

Embodiment 84 provides the method of any one of Embodiments 76-83, wherein at least a portion of the of the dielectric resin fills the slot as the fourth conducting layer is laminated to the second conducting layer.

Embodiment 85 provides the method of any one of Embodiments 76-84, wherein the dielectric resin comprises the second dielectric material.

Embodiment 86 provides the method of any one of Embodiments 76-85, and further comprising:

plating the slot with a layer of conducting material that connects the first conducing material to the second conducting material.

Embodiment 87 provides the method of any one of Embodiments 76-86, wherein the first conducting layer is formed from copper.

Embodiment 88 provides the method of any one of Embodiments 76-87, wherein the second conducting layer is formed from copper.

Embodiment 89 provides the method of any one of Embodiments 76-88, wherein the first dielectric material is selected from the group consisting of, a polyimide, a bismaleimide-triazine (BT) resin, an epoxy resin, a polyurethane, a benzocyclobutene (BCB), a high-density polyethylene (HDPE), or combinations thereof.

Embodiment 90 provides the method of any one of Embodiments 76-89, wherein the fiber is a glass fiber.

Embodiment 91 provides the method of any one of Embodiments 76-90, wherein the dielectric material is about 80% (w/w) to about 98% (w/w) of the dielectric layer.

Embodiment 92 provides the method of any one of Embodiments 76-91, wherein the slot has a circular profile.

Embodiment 93 provides the method of any one of Embodiments 76-92, wherein the slot has a square profile.

Embodiment 94 provides the method of any one of Embodiments 76-93, wherein the slot has a rectangular profile.

Embodiment 95 provides the method of any one of Embodiments 76-94, wherein the slot has a generally elliptical profile.

Embodiment 96 provides the substrate of any one of Embodiments 76-95, wherein the slot has a generally elongated race-track profile.

Embodiment 97 provides the method of any one of Embodiments 76-96, wherein the slot has a polygonal profile.

Embodiment 98 provides the method of any one of Embodiments 76-97, wherein a profile of the slot is the same as a profile of at least one of another of the slots.

Embodiment 99 provides the method of any one of Embodiments 76-98, and further comprising:

drilling a second slot through the laminate.

Embodiment 100 provides the method of any one of Embodiments 76-99, and further comprising:

filling the second slot with the second dielectric material.

1-25. (canceled)

26. A substrate for a semiconductor comprising:
a first conducting layer comprising:
a first surface; and
an opposite second surface;
a second conducting layer extending in a direction substantially parallel to the first conducting layer, comprising:
a third surface; and
an opposite fourth surface;
a first dielectric layer disposed between the second surface of the first conducting layer and the third surface of the second conducting layer comprising:
a first dielectric material; and
a plurality of slots extending between the first conducting layer and the second conducting layer, wherein each of the slots is defined by an internal surface of the first dielectric layer and at least one of the first conducting layer and the second conducting layer, and the first dielectric layer.

27. The substrate of claim 26, wherein the first conducting layer is formed from copper.

28. The substrate of claim 26, wherein the second conducting layer is formed from copper.

29. The substrate of claim 26, wherein each of the slots is defined by an internal surface of the first dielectric layer, the first conducting layer, and the second conducting layer.

30. The substrate of claim 26, wherein a set of the slots are arranged in a first row of slots extending from a first end of the substrate to a second end of the substrate.

31. The substrate of claim 30, wherein a second set of the slots are arranged in a second row of slots extending from the first end of the substrate to the second end of the substrate.

32. A semiconducting device comprising:
a substrate comprising:
a first conducting layer: comprising
a first surface; and
an opposite second surface;
a second conducting layer extending in a direction substantially parallel to the first conducting layer, comprising:
a third surface; and
an opposite fourth surface;
a first dielectric layer disposed between the second surface of the first conducting layer and the third surface of the second conducting layer, comprising:
a first dielectric material; and
reinforcing fibers; and
a plurality of pedestals extending through the first conducting layer, the first dielectric layer and the second conducting layer, wherein the pedestals are each formed from a second dielectric material;
an electrical component connected to the substrate; and
a mold encasing the substrate and the electrical component.

33. The semiconducting device of claim 32, wherein each of the pedestals is free of the fiber.

34. The semiconducting device of claim 32, wherein the first conducting layer is formed from copper.

35. The semiconducting device of claim 32, wherein the second conducting layer is formed from copper.

36. The semiconducting device of claim 32, wherein the first dielectric material is selected from the group consisting of, a polyimide, a bismaleimide-triazine (BT) resin, an epoxy resin, a polyurethane, a benzocyclobutene (BCB), a high-density polyethylene (HDPE), or combinations thereof.

37. The semiconducting device of claim 32, wherein the dielectric material forming each of the pedestals is the same dielectric material of the dielectric layer.

38. The semiconducting device of claim 32, wherein the pedestals are more flexible than the first dielectric layer.

39. The semiconducting device of claim 32, and further comprising:
a plurality of strips fooled from a conducting material, wherein each of the strips is disposed between at least one of the pedestals and the first dielectric layer.

40. The semiconducting device of claim 32, wherein the substrate is undergoes less warpage in response to being exposed to a temperature at or above room temperate as compared to a substrate that does not include at least one of the pedestals.

41. A method of forming a substrate comprising:
drilling a slot through a laminate, wherein the laminate comprises:
a first conducting layer comprising:
a first surface; and
an opposite second surface;
a second conducting layer extending in a direction substantially parallel to the first conducting layer, comprising:
a third surface; and
an opposite fourth surface; and
a first dielectric layer disposed between the second surface of the first conducting layer and the third surface of the second conducting layer comprising:
a first dielectric material; and
reinforcing fibers; and
filling the slot with a second dielectric material.

42. The method of claim 41, and further comprising laminating a third conducting layer to the first conducting layer.

43. The method of claim 42, wherein at least a portion of the of the dielectric resin fills the slot as the third conducting layer is laminated to the first conducting layer.

44. The method of claim 42, and further comprising laminating a fourth conducting layer to the second conducting layer.

45. The method of claim 44, wherein at least a portion of the of the dielectric resin fills the slot as the fourth conducting layer is laminated to the second conducting layer.
